(19) United States
(12) Patent Application Publication
(10) Pub. No.: US 2024/0282757 A1
(43) Pub. Date: Aug. 22, 2024

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Ruoxiang LI, Beijing (CN); Lu LI, Beijing (CN); Yao HU, Beijing (CN); Qian CHEN, Beijing (CN); Chenbiao YANG, Beijing (CN); Liang XIA, Beijing (CN)

(21) Appl. No.: 18/025,066

(22) PCT Filed: Jun. 20, 2022
(86) PCT No.: PCT/CN2022/099831

§ 371 Date: Mar. 7, 2023

(51) Int. Cl. H01L 25/075; H01L 33/58

(52) U.S. Cl. CPC H01L 25/0753; H01L 33/58

(57) ABSTRACT

Provided is a display panel. The display panel includes: a substrate; a plurality of light emitting elements, disposed on the substrate; an optical adjustment pattern, disposed on a side, departing from the substrate, of the light emitting elements, wherein the optical adjustment pattern includes a first bump structure corresponding to at least one light emitting element of the plurality of light emitting units, an overlapping region being present between an orthographic projection of the first bump structure on the substrate and an orthographic projection of the light emitting element corresponding to the first bump structure on the substrate, an area of the overlapping region being less than an area of the orthographic projection of the light emitting element on the substrate; and a first planarization layer, disposed on a side, departing from the light emitting element, of the optical adjustment pattern.

### CROSS-REFERENCE TO RELATED APPLICATION

This application is a U.S. national phase application based on PCT/CN2022/099831, filed on Jun. 20, 2022, the disclosure of which is incorporated herein by reference in its entirety.

### TECHNICAL FIELD

The present application related the field of display technology, and in particular to a display panel and a display device.

### BACKGROUND OF THE INVENTION

Active matrix organic light emitting diode, with its low power consumption, self-luminous, high color saturation, fast response, wide viewing angle and flexibility, is increasingly applied in the field of high-performance displays.

### SUMMARY OF THE INVENTION

Embodiments of the present application provide a display panel and a display device. The technical solutions are as follows.

According to some embodiments of the present disclosure, a display panel is provided. The display panel includes:
a substrate;
a plurality of light emitting elements, disposed on the substrate;
an optical adjustment pattern, disposed on a side, departing from the substrate, of the light emitting elements, the optical adjustment pattern includes a first bump structure corresponding to at least one light emitting element of the plurality of light emitting units, an overlapping region being present between an orthographic projection of the first bump structure on the substrate and an orthographic projection of the light emitting element corresponding to the first bump structure on the substrate, an area of the overlapping region being less than an area of the orthographic projection of the light emitting element on the substrate;
a first planarization layer, disposed on a side, departing from the light emitting element, of the optical adjustment pattern, wherein a refractive index of the first planarization layer is greater than a refractive index of the optical adjustment pattern.

In some embodiments, the light emitting elements include at least two types of light emitting elements, and the first bump structure includes at least one sub-bump;
wherein the at least two types of light emitting elements include a first color light emitting element and a second color light emitting element, a sub-bump parameter of the first bump structure corresponding to the first color light emitting element is different from a sub-bump parameter of the first bump structure corresponding to the second color light emitting element, and the sub-bump parameter includes at least one of a quantity and a size of the sub-bumps.

In some embodiments, in at least one direction parallel to the substrate, an attenuation parameter of the first color light emitting element is less than an attenuation parameter of the second color light emitting element, the attenuation parameter being a ratio of a luminance of the light emitting element at a specified emitting angle to a maximum luminance of the light emitting element in the at least one direction parallel to the substrate;
wherein a quantity of the sub-bumps of the first bump structure corresponding to the first color light emitting element is greater than a quantity of the sub-bumps of the first bump structure corresponding to the second color light emitting element.

In some embodiments, in at least one direction parallel to the substrate, an attenuation parameter of the first color light emitting element is less than an attenuation parameter of the second color light emitting element, the attenuation parameter being a ratio of a luminance of the light emitting element at a specified emitting angle to a maximum luminance of the light emitting element in the at least one direction parallel to the substrate;
wherein at least one sub-bump of the first bump structure is a strip bump, and a length of the strip bump corresponding to the first color light emitting element is greater than a length of the strip bump corresponding to the second color light emitting element.

In some embodiments, the plurality of light emitting elements include at least one target light emitting element, an attenuation parameter of the target light emitting element in a first direction being less than an attenuation parameter in a second direction, the first direction and the second direction being parallel to the substrate, the first direction being perpendicular to the second direction, the attenuation parameter being a ratio of a luminance of the light emitting element at a specified emitting angle to a maximum luminance of the light emitting element in the at least one direction parallel to the substrate;
wherein the first bump structure includes at least one sub-bump, the at least one sub-bump of the first bump structure is a strip bump, a length direction of the strip bump corresponding to the target light emitting element being parallel to the second direction.

In some embodiments, the first bump structure includes a plurality of sub-bumps, the sub-bumps being strip bumps, and length directions of the plurality of the strip bumps being intersected with each other.

In some embodiments, the first bump structure includes a plurality of sub-bumps, the sub-bumps are strip bumps, length directions of the plurality of the strip bumps being parallel to each other, the plurality of the strip bumps being spaced apart.

In some embodiments, the first bump structure includes at least one sub-bump, the at least one sub-bump of the first bump structure being a block bump, an edge of an orthographic projection of the block bump on the substrate being spaced from an edge of an orthographic projection of the light emitting element corresponding to the block bump on the substrate.

In some embodiments, the display panel further includes a pixel definition layer, wherein the pixel definition layer is disposed on a side, facing towards the substrate, of the optical adjustment pattern, the pixel definition layer comprises a plurality of pixel openings, and the light emitting elements are disposed in the pixel openings;
wherein the optical adjustment pattern further includes a second bump structure, the second bump structure comprises a plurality of first openings, an orthographic projection of the pixel opening on the substrate is within an orthographic projection of the first opening on the substrate, and an orthographic projection of the first bump structure on the substrate is within the orthographic projection of the first opening on the substrate.

In some embodiments, the first bump structure and the second bump structure are disposed in one layer and are formed by one-time patterning process.

In some embodiments, the first bump structure includes at least one sub-bump, the sub-bump being a strip bump, both ends of the strip bump being connected to the second bump structure.

In some embodiments the first bump structure includes at least one sub-bump, the sub-bump being a strip bump, an orthographic projection of the strip bump on the substrate being in contact with two opposite edges of an orthographic projection of the pixel opening on the substrate along a third direction, the third direction being a length direction of the strip bump.

In some embodiments, a center of an orthographic projection of the first bump structure on the substrate is coincident with a center of an orthographic projection of the light emitting element corresponding to the first bump structure on the substrate.

In some embodiments, a center of an orthographic projection of the first bump structure on the substrate is in a determined direction of a center of an orthographic projection of the light emitting element corresponding to the first bump structure on the substrate.

In some embodiments, the first bump structure includes at least one sub-bump, the sub-bump has a top surface, a bottom surface and a side surface connecting the bottom surface and the top surface, and an angle between the side surface and the bottom surface is an acute angle.

In some embodiments, the acute angle ranges from 60° to 90°.

In some embodiments, the first bump structure includes at least one sub-bump, a thickness of the sub-bump being greater than or equal to 4 μm.

In some embodiments, the sub-bump is a strip bump, and a width of the strip bump ranges from 5 μm to 10 μm in a direction parallel to the substrate; or

the sub-bump is a block bump, and a width of the block bump ranges from 5 μm to 10 μm in a direction parallel to the substrate.

In some embodiments, the display panel further includes an organic package layer, the organic package layer is disposed on a side, departing from the substrate, of the first planarization layer and the optical adjustment pattern;
wherein the first planarization layer comprises a third bump structure, an orthographic projection of the light emitting element on the substrate and an orthographic projection of the optical adjustment pattern on the substrate being within an orthographic projection of the third bump structure on the substrate, a refractive index of the third bump structure being greater than a refractive index of the organic package layer.

According to some embodiments of the present disclosure, a display device is provided, including: a power supply assembly, and the above display panel, wherein the power supply assembly is configured to supply power to the display panel.

### BRIEF DESCRIPTION OF DRAWINGS

In order to describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art can still derive other drawings from these accompanying drawings without creative efforts.

FIG. 1 is a schematic diagram of the structure of a display panel;

FIG. 2 is a schematic diagram of a cross-sectional structure of the display panel at A1-A2 illustrated in FIG. 1;

FIG. 3 is a color trajectory diagram of the display panel illustrated in FIG. 1;

FIG. 4 is a schematic diagram of the structure of the display panel according to some embodiments of the present application;

FIG. 5 is a schematic diagram of a cross-sectional structure of the display panel at B1-B2 illustrated in FIG. 4;

FIG. 6 is a schematic diagram of the light path of the display panel illustrated in FIG. 5;

FIG. 7 is a color trajectory diagram of the display panel illustrated in FIG. 4;

FIG. 8 is a schematic diagram of the structure of another display panel according to some embodiments of the present application;

FIG. 9 is a schematic diagram of a cross-sectional structure of the display panel at C1-C2 illustrated in FIG. 8;

FIG. 10 is a schematic diagram of the structure of another display panel according to some embodiments of the present application;

FIG. 11 is a schematic diagram of the structure of another display panel according to some embodiments of the present application;

FIG. 12 is a schematic diagram of the structure of another display panel according to some embodiments of the present application;

FIG. 13 is a schematic diagram of a cross-sectional structure of the display panel at D1-D2 illustrated in FIG. 12;

FIG. 14 is a schematic diagram of the structure of another display panel according to some embodiments of the present application;

FIG. 15 is a schematic diagram of a cross-sectional structure of the display panel at E1-E2 illustrated in FIG. 14;

FIG. 16 is a schematic diagram of the structure of another display panel according to some embodiments of the present application;

FIG. 17 is a schematic diagram of the structure of another display panel according to some embodiments of the present application;

FIG. 18 is a schematic diagram of the structure of another display panel according to some embodiments of the present application;

FIG. 19 is a schematic diagram of a cross-sectional structure of the display panel at G1-G2 illustrated in FIG. 18;

FIG. 20 is a schematic diagram of the structure of another display panel according to some embodiments of the present application;

FIG. 21 is a schematic diagram of a cross-sectional structure of the display panel at H1-H2 illustrated in FIG. 20;

FIG. 22 is a schematic diagram of the structure of another display panel according to some embodiments of the present application;

FIG. 23 is a schematic diagram of the structure of another display panel according to some embodiments of the present application;

FIG. 24 is a schematic diagram of the structure of another display panel according to some embodiments of the present application;

FIG. 25 is a schematic diagram of a cross-sectional structure of the display panel at J1-J2 illustrated in FIG. 24; and

FIG. 26 is a schematic diagram of the structure of another display panel according to some embodiments of the present application.

By means of the accompanying drawings above, definite embodiments of the present application have been illustrated and will be described in detail later. These accompanying drawings and text description are not intended to limit the scope of the present application conception by any means, but rather to illustrate the concepts of the present application for those skilled in the art by reference to particular embodiments.

### DETAILED DESCRIPTION

For clearer descriptions of the objectives, technical solutions, and advantages of the present disclosure, the following further describes implementations of the present disclosure in detail with reference to the accompanying drawings.

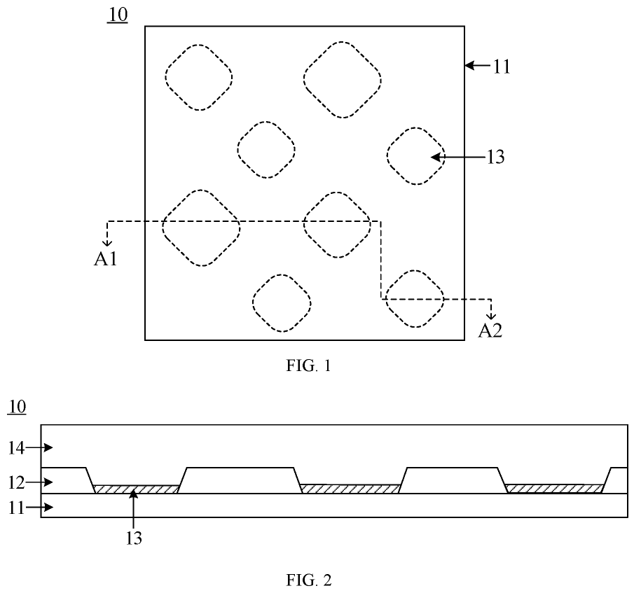

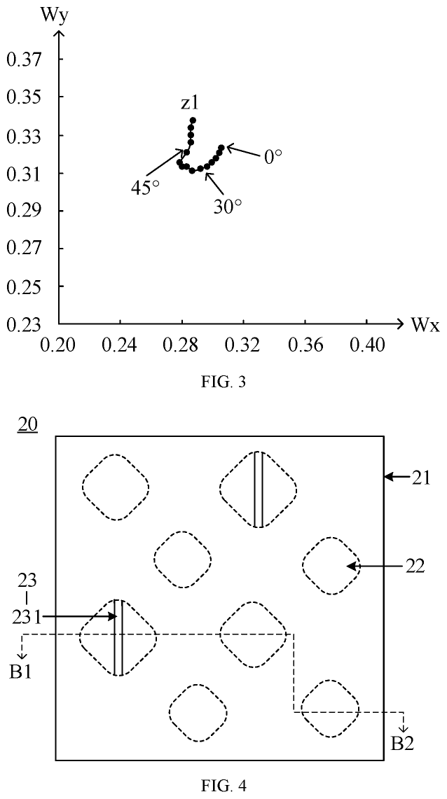

FIG. 1 is a schematic diagram of the structure of a display panel. FIG. 2 is a schematic diagram of a cross-sectional structure of the display panel at A1-A2 illustrated in FIG. 1. FIG. 3 is a color trajectory diagram of the display panel illustrated in FIG. 1. The display panel includes: a substrate 11, a pixel definition layer 12, a plurality of light emitting elements 13 and a package layer 14. The substrate 11 includes pixel driver circuitry configured to drive the light emitting elements, and the package layer 14 has a touch layer disposed on a side, distal from the light emitting elements 13, of the package layer 14.

The plurality of light emitting elements 13 includes red light emitting elements for emitting red light, green light emitting elements for emitting green light, and blue light emitting elements for emitting blue light. That is, each pixel of the display panel 10 is composed of a red light emitting element for emitting red light, a green light emitting element for emitting green light, and a blue light emitting element for emitting blue light, such that red, green, and blue light are mixed to form the color displayed by each pixel, which enables the display panel 10 to display a color picture. Because the micro-cavity structure, shape and size of different color light emitting elements are different, the luminance of at least part of the light emitting elements changes with the change of the light emitting angle. Usually, with the light emitting angle increasing, the luminance of the light emitting element sequentially decreases, resulting in that the luminance of the light emitting element in the larger light emitting angle decreases, compared to the luminance of the light emitting element in the smaller light emitting angle. The light emitted from different color light emitting elements changes inconsistently with the light emitting angle increasing, which leads to the problem of color shift in the display panel.

FIG. 3 illustrates the color shift trajectory z1 of the actual color displayed by the display panel 10 in the Commission Internationale de l'Eclairage (CIE) chromaticity diagram when displaying a white screen with different viewing angles. The horizontal coordinate Wx and the vertical coordinate Wy of the color trajectory graph indicate the chromaticity values. The curve z1 represent the trend of the color trajectory of the light emitting angle (i.e., the view angle of the viewer) from 0° to 90° of the display panel 10 in one direction parallel to the substrate of the display panel 10. Referring to FIG. 3, it can be seen that the color of the display panel 10, as the light emitting angle increases, is first pink (from 0° to 30°), then blue (from 30° to 45°), and then cyan (from 45° to 90°). Specifically, in the case that the luminance of a light emitting element in the display panel changes more than other light emitting elements with the light emitting angle increasing, the display panel has effect of cyan or pink in large viewing angle when displaying a white light.

Embodiments of the present application provide a display panel and a display device capable of solving the problems in the above related technology.

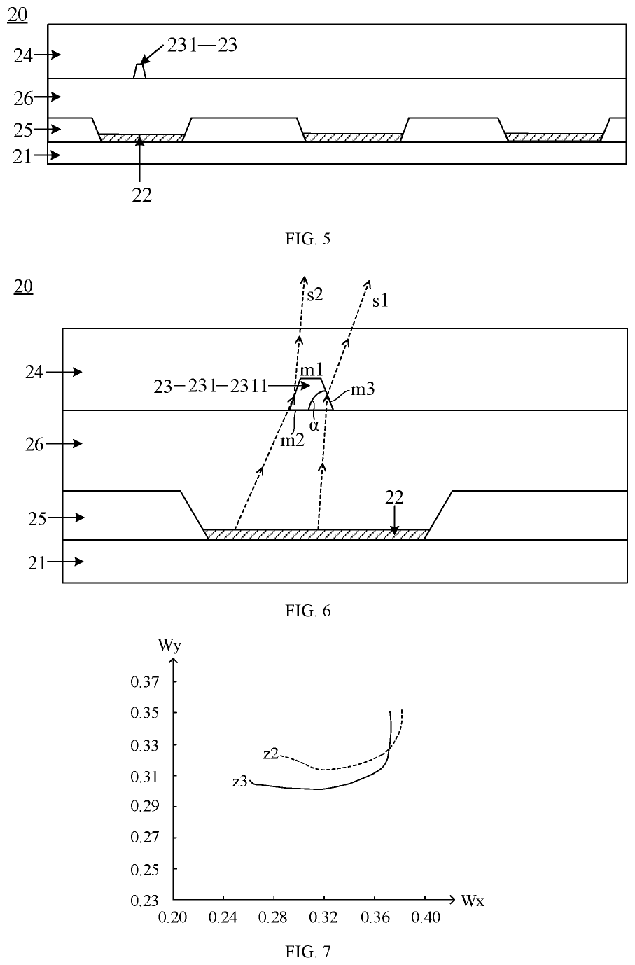

Referring to FIG. 4 and FIG. 5, FIG. 4 is a schematic structure of a display panel according to some embodiments of the present application, and FIG. 5 is a schematic cross-sectional structure of the display panel at B1-B2 illustrated in FIG. 4. The display panel 20 includes: a substrate 21, a plurality of light emitting elements 22, an optical adjustment pattern 23, and a first planarization layer 24.

The plurality of light emitting elements 22 are disposed on the substrate 21, and the plurality of light emitting elements 13 include a plurality types of light emitting elements for emitting light with different colors. The optical adjustment pattern 23 is disposed on a side of the light emitting element 22 departing from the substrate 21, that is, the optical adjustment pattern 23 is disposed on the light emitting side of the light emitting element 22.

The optical adjustment pattern 23 includes a first bump structure 231 corresponding to at least one light emitting element 22 of the plurality of light emitting elements 22, an overlapping region is arranged between an orthographic projection of the first bump structure 231 on the substrate 21 and an orthographic projection of the light emitting element 22 corresponding to the first bump structure 231 on the substrate 21, and the area of the overlapping region is less than the area of the orthographic projection of the light emitting element 22 on the substrate 21.

The first planarization layer 24 is disposed on the side of the optical adjustment pattern 23 departing from the light emitting element 22, wherein the refractive index of the first planarization layer 24 is greater than the refractive index of the optical adjustment pattern 23. The first planarization layer 24 covers the optically adjusted pattern 23. In this way, the first bump structure 231 is disposed on the light emitting side of the corresponding light emitting element 22 to adjust the light emitting angle of a portion of the light emitted from the light emitting element 22 (the portion of the light irradiated to the first bump structure 231).

As shown in FIG. 6, FIG. 6 is a schematic diagram of the light path of the display panel illustrated in FIG. 5. It should be noted that FIG. 6, for the purpose of clearly showing the direction of the light path of the light emitted by the light emitting element 22 irradiating to the first bump structure 231, shows only a portion of the light path of the light beam emitted by the light emitting element 22, which does not represent the amount of light emitted by the light emitting element 22 from the direction illustrated in the FIG. 6. As can be seen from FIG. 6, the first light beam s1 emitted by the light emitting element 22 irradiates to the interior of the first bump structure 231 and exits from the surface of the first bump structure 231 to the first planarization layer 24. Because the refractive index of the first planarization layer 24 is greater than the refractive index of the first bump structure 231, the light emitting angle of the first light beam s1 emitted by the light emitting element 22 becomes larger, prior to emitting to the first bump structure 231. The light emitting angle refers to the light emitting angle between the light beam emitted by the light emitting element 22 and the normal of the light emission surface of the display panel 20, and the normal of the light emission surface of the display panel 20 is perpendicular to the substrate 21.

The second light beam s2 emitted by the light emitting element 22 enters the interior of the first planarization layer 24, irradiates to the surface of the first bump structure 231, and is total reflected at the surface of the first bump structure 231, such that the light emitting angle of the second light beam s2 emitted by the light emitting element 22 becomes smaller, prior to emitting to the first bump structure 231.

The first bump structure 231 has the following two effects on the light emitted by the light emitting element 22. The first effect is increasing the light emitting angle of at least part of the light beam (e.g. the first light beam s1) emitted by the light emitting element 22, such that the amount of light emitted by the light emitting element 22 at a larger light emitting angle can be increased. The second effect is reducing the light emitting angle of at least part of the light beam (e.g. the second light beam s2) emitted by the light emitting element 22, such that the amount of light emitted by the light emitting element 22 at a smaller light emitting angle can be increased. According to the experimental results, the first effect on the light emitted by the light emitting element 22 is greater than the second effect. In this way, the first bump structure 231 can adjust a portion of the light emitted by the corresponding light emitting element 22 with a smaller light emitting angle to a larger light emitting angle, such that the light emitting angle of the portion of the light emitted by the corresponding light emitting element 22 is increased, and the uniformity of the light emitted by the light emitting element 22 at each light emitting angle is improved. Avoiding the luminance difference of the light emitting element 22 is too large as the light emitting angle increases improves the uniformity of the light of the display panel 20.

In summary, embodiments of the present application provide a display panel. The display panel includes: a substrate, a plurality of light emitting elements, an optical adjustment pattern, and a first planarization layer. A first bump structure of the optical adjustment pattern is disposed in the light emitting direction of at least one light emitting element. The optical adjustment pattern increases the light emitting angle of at least part of the light emitted by the light emitting element, and improves the uniformity of the brightness of the light emitting element at different light emitting angles, and improves the display effect of the display panel.

Optionally, as shown in FIG. 7, FIG. 7 is a color trajectory diagram of the display panel illustrated in FIG. 4. FIG. 7 illustrates the color shift trajectory z3 of the actual color displayed by the display panel 20 in the CIE chromaticity diagram with different viewing angles in the case that the display panel 20 is displaying a white screen. The horizontal coordinate Wx and the vertical coordinate Wy of the color trajectory diagram represent the chromaticity values. The curve z2 represents the color shift trajectory in the CIE chromaticity diagram of the actual color displayed by the display panel without setting the optical adjustment pattern 23 in the related technology. As can be seen from FIG. 7, by setting the optical adjustment pattern 23, the color offset trajectory of the display panel is adjusted, and thus the display effect of the display panel is adjusted.

Optionally, as shown in FIG. 6, the first bump structure 231 includes at least one sub-bump 2311, the sub-bump 2311 has a top surface m1, a bottom surface m2, and a side surface m3 connecting the bottom surface m2 and the top surface m1, and an acute angle α is between the side surface m3 and the bottom surface m2. The acute angle α ranges from 60° to 90°. In this way, the light emitted by the light emitting element 22, upon passing through the side surface of the first bump structure 231, the light emitting angle of the light is increased, the light uniformity of the light emitting element 22 at each light emitting angle is improved, and the display effect of the display panel is improved.

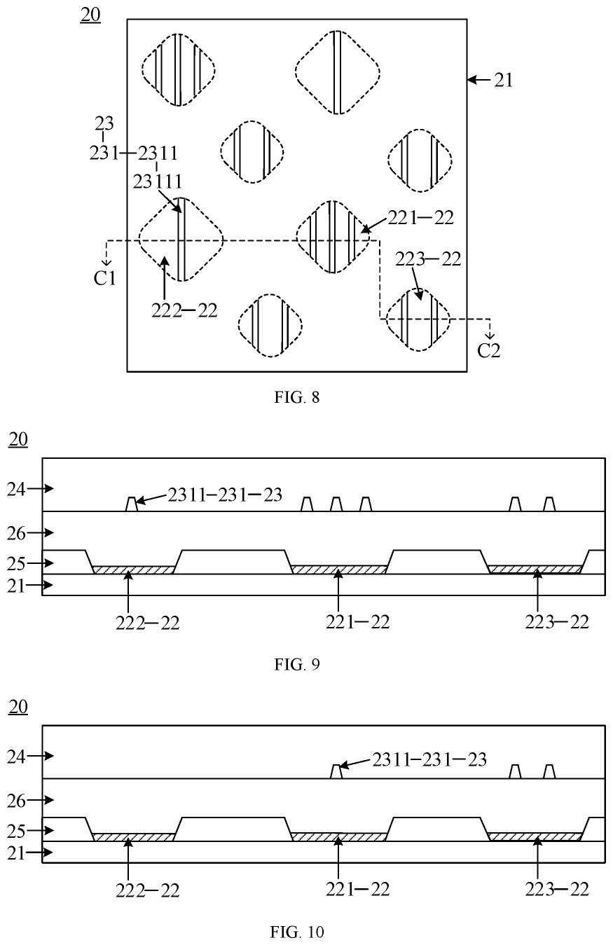

Optionally, as shown in FIG. 8, which is a schematic structure of another display panel according to some embodiments of the present application, and FIG. 9 is a schematic diagram of a cross-sectional structure of the display panel at C1-C2 illustrated in FIG. 8. The light emitting element 22 includes at least two types of light emitting elements 22, and the first bump structure 231 includes at least one sub-bump 2311.

The at least two types of light emitting elements 22 include a first color light emitting element 221 and a second color light emitting element 222, and the first color light emitting element 221 and the second color light emitting element 222 emits light of different colors. Because there are differences in at least one of the micro cavity structure, the shape, and the dimensions of the different kinds of light emitting elements 22, in the case that the light emitting angle between the human eye observation direction and the normal of the light emitting surface of the display panel 20 is large (e.g., the light emitting angle is 45 degrees to 60 degrees), the difference between the luminance of the light emitted by the first color light emitting element 221 and the light emitted by the second color light emitting element 222 at the same viewing angle is large, making the screen displayed on the display panel 20 more prone to color shift problems, which leads to poorer display effect of the display panel 20.

The sub-bump parameters of first color light emitting element 221 corresponding to the first bump structure 231 and the sub-bump parameters of the second color light emitting element 222 corresponding to the first bump structure 231 are different, and the sub-bump parameters include at least one of the quantity and size of the sub-bump 2311. The light emitted from different kinds of light emitting elements 22 is adjusted by setting different first bump structures 231 for different types of light emitting elements 22, such that the change of the luminance of the light emitted by the first color light emitting element 221 is consist with the change of the luminance of the light emitted by the first color light emitting element 221 during the process of changing the light emitting angle. The problem of color shift of the display panel is avoided when displaying the screen at different light emitting angles, and the display effect of the display panel 20 is improved.

The at least two light emitting elements 22 further include a third color light emitting element 223, and the sub-bump parameter of the first bump structure 231 corresponding to the third color light emitting element 223 is different from the sub-bump parameters of the first bump structure 231 corresponding to the first color light emitting element 221 and the second color light emitting element 222. Alternatively, the sub-bump parameter of the first bump structure 231 corresponding to the third color light emitting element 223 is different from the sub-bump parameter of the first bump structure 231 corresponding to the first color light emitting element 221, and the sub-bump parameter of the first bump structure 231 corresponding to the third color light emitting element 223 is the same as the sub-bump parameter of the first bump structure 231 corresponding to the second color light emitting element 222.

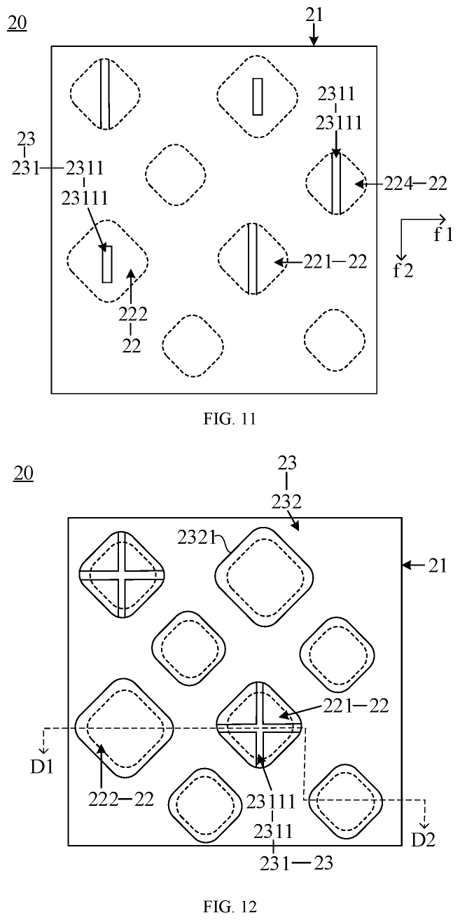

It should be noted that, for easy understanding, the embodiment of the present application is illustrated in FIG. 8 by the example that the optical adjustment pattern 23 adjusts the light emitted by the first color light emitting element 221 and the second color light emitting element 222 simultaneously. As shown in FIG. 10, FIG. 10 is a schematic diagram of the structure of another display panel according to some embodiments of the present application. The optical adjustment pattern 23 adjusts the light emitted by the first color light emitting element 221 or the second color light emitting element 222. That is, the light emitted from the first color light emitting element 221 or the second color light emitting element 222 is provided without the first bump structure 231 in the light emitting direction.

Optionally, as shown in FIG. 8, the attenuation parameter of the first color light emitting element 221 is less than the attenuation parameter of the second color light emitting element 222 in at least one direction parallel to the substrate 21, and the attenuation parameter is the ratio of the luminance of the light emitting element 22 at the specified light emitting angle to the maximum luminance of the light emitting element 22 in at least one direction parallel to the substrate 21. The range of the specified light emitting angle is from 15° to 90°.

That is, in at least one direction parallel to the substrate 21, the attenuation parameter refers to the ratio of the luminance of the light beam at any one light emitting angle from the light emitting element 22 to the maximum luminance of the light emitting element 22, during the light emitting angle of the light beam changing from 0° to 90°. In the case that the ratio is less, the degree of attenuation of the luminance of the light emitting element is greater, and the difference between the luminance of the large angle of the element and the luminance of the small angle (frontal) light is greater.

The quantity of sub-bumps 2311 in the first bump structure 231 corresponding to the first color light emitting element 221 is greater than the quantity of sub-bumps 2311 in the first bump structure 231 corresponding to the second color light emitting element 222. The first bump structure 231 corresponding to the first color light emitting element 221 is configured to adjust the light emitted by the first color light emitting element 221 to increase the light emitting angle of light emitted by the first color light emitting element 221 in the case that a portion of the light is emitted from the display panel. The second color light emitting element 222 corresponding to the first bump structure 231 is configured to adjust the light emitted by the second color light emitting element 222, in order to increase the light emitting angle of light emitted by the second color light emitting element 222 from the display panel. Moreover, the amount of light emitted by the first color light emitting element 221 through the optical adjustment pattern 23 is greater than the amount of light emitted by the second color light emitting element 221 through the optical adjustment pattern 23.

In this way, the optical adjustment layer 24 can adjust the light emitting angle of the light emitted by the first color light emitting element 221 and the second color light emitting element 222 in the display panel 20, such that the attenuation parameter of the light emitted by the first color light emitting element 221 is consist with the attenuation parameter of the light emitted by the first color light emitting element 221 as much as possible during the change of the light emitting angle of the display panel 20. Therefore, the display panel 20 can avoid the phenomenon of color shift when the display panel is displayed at different viewing angles, and the display effect of the display panel can be improved.

In an optional embodiment, as shown in FIG. 10, the quantity of the first bump structures 231 corresponding to the second color light emitting element 222 is zero, such that the light emitting angle of light emitted from the second color light emitting element 222 is not adjusted in the case that the light is emitted from the display panel. The quantity of sub-bumps 2311 of the first bump structure 231 corresponding to the first color light emitting element 221 is greater than or equal to 1. In this way, the light emitting angle of light emitted from the display panel by the first color light emitting element 221 can be adjusted to avoid the phenomenon of color shift in the case that the display panel 20 is displayed in the screen at different viewing angles.

Optionally, as shown in FIG. 11, FIG. 11 is a schematic diagram of the structure of another display panel according to some embodiments of the present application. The attenuation parameter of the first color light emitting element 221 is less than the attenuation parameter of the second color light emitting element 222 in at least one direction parallel to the substrate 21, and the attenuation parameter is the ratio of the light emitting element 22 at the specified light emitting angle in at least one direction parallel to the substrate 21 luminance to the maximum luminance of the light emitting element 22 in at least one direction parallel to the substrate 21.

At least one sub-bump 2311 of the first bulge structure 231 is a strip bump 23111, and the length of the strip bump 23111 corresponding to the first color light emitting element 221 is greater than the length of the strip bump 23111 corresponding to the second color light emitting element 222. The ratio of the length and width of the strip bump 23111 is greater than or equal to 2.

Because the length of the strip bump 23111 is longer, the strip bump 23111 can adjust more light emitted by the light emitting element 22 with a smaller light emitting angle to the light with a larger light emitting angle, such that the strip bump 23111 can adjust the attenuation parameter of the corresponding light emitting element 22 to be larger. Therefore, by setting the strip bump 23111 with different lengths, the light emitting angle of a portion of the light emitted form the first color light emitting element 221 and the second color light emitting element 222 of the display panel 20 is adjusted, such that the attenuation parameter of the light emitted by the first color light emitting element 221 is consist with the attenuation parameter of the light emitted by the second color light emitting element 222 as much as possible during the process of changing the light emitting angle. The phenomenon of color shifts of the display panel 20 in different viewing angles can be avoided in the case that display panel displays a screen, and the display effect of the display panel 20 is improved.

Optionally, as shown in FIG. 11, the plurality of light emitting elements 22 includes at least one target light emitting element 224, the attenuation parameter of the target light emitting element 224 in the first direction f1 is less than the attenuation parameter in the second direction f2, the first direction f1 and the second direction f2 is parallel to the direction of the substrate 21, and the first direction f1 is perpendicular to the second direction f2.

The first bump structure 231 includes at least one sub-bump 2311, the at least one sub-bump 2311 of the first bump structure 231 is a strip bump 23111, and the length direction of the strip bump 23111 corresponding to the target light emitting element 224 is parallel to the second direction f2.

In the case that the sub-bump 2311 is a strip bump 23111, the side surface extending along the length direction of the strip bump 23111 has a greater influence on the light emitting angle of the light emitted from the light emitting element 22, that is, the strip bump 23111 adjusts the light emitting angle of the light emitting element 22 in the width direction of the strip bump 23111, such that the light emitting angle of the light emitted by the light emitting element 22 in a plurality of direction is adjusted by flexibly setting the length direction of the strip bump 23111, and the attenuation parameter of the light emitting element 22 in a plurality of directions is flexibly adjusted. Exemplarily, the length direction of the strip bump 23111 is the second direction f2, the light emitting angle of a portion of the light emitted by the light emitting element 22 in the first direction f1 is increased, and the color shift of the display panel in the first direction f1 is adjusted. The first direction f1 is perpendicular to the second direction f2. Specifically, the side surface extending along the length direction of the strip bump 23111 is oriented in the direction in which the color shift of the display panel needs to be adjusted.

In this way, the difference between the attenuation parameter of the target light emitting element 224 in the first direction f1 and the attenuation parameter of the target light emitting element 224 in the second direction f2 can be reduced by increasing the light emitting angle of at least some of the light emitted by the target light emitting element 224 in the first direction f1 by the first bump structure 231. The problem of color shifts of the display panel 20 is avoided when the screen is displayed in different directions, and the display effect of the display panel is improved.

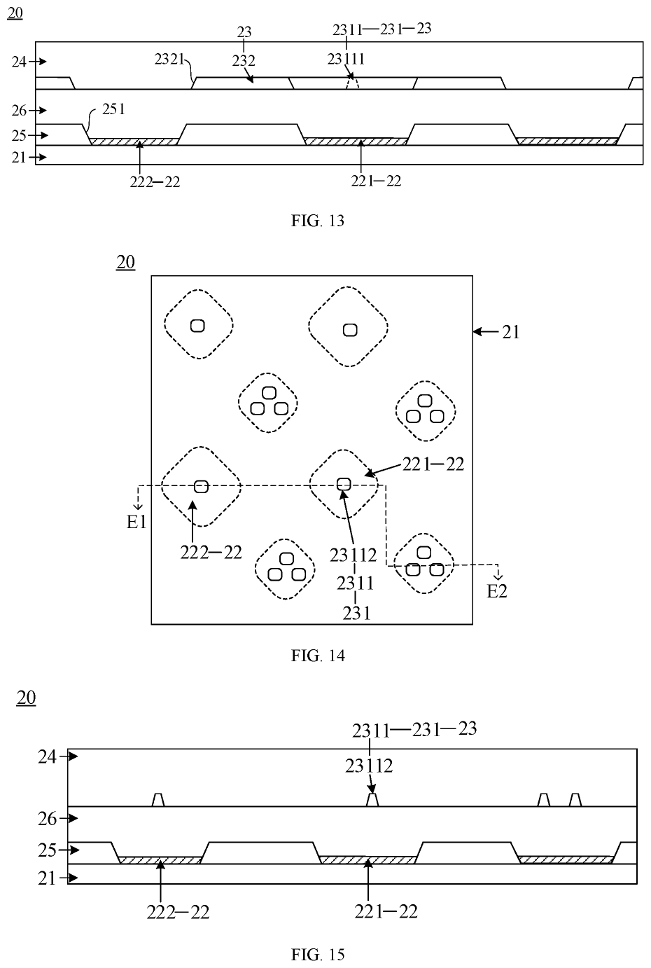

Optionally, as shown in FIG. 12 and FIG. 13, FIG. 12 is a schematic diagram of the structure of another display panel according to some embodiments of the present application, and FIG. 13 is a schematic diagram of a cross-sectional structure of the display panel at D1-D2 illustrated in FIG. 12. The first bump structure 231 includes a plurality of sub-bumps 2311, the sub-bumps 2311 are strip bumps 23111, and angles are disposed between the length directions of the plurality of strip bumps 23111. The plurality of strip protrusions 23111 have different extending directions to adjust the light emitting angle in the plurality of directions of the light emitting element 22 corresponding to the first bump structure 231. Exemplarily, the plurality of strips 23111 can be “cross-shaped”, “beige” and various other shapes.

Optionally, as shown in FIG. 8, the first bump structure 231 includes a plurality of sub-bumps 2311, and the sub-bumps 2311 are strips bumps 23111, and the lengths of the plurality of strips bumps 23111 are parallel to each other, and the plurality of strips bumps 23111 are spaced apart from each other. The attenuation parameter of the light emitting element 22 in one direction can be adjusted by adjusting the quantity of strip bumps 23111 corresponding to the light emitting element 22. Exemplarily, the quantity of strip bumps 23111 corresponding to the first color light emitting element 221 is three, and the length direction of all three strip bumps 23111 is the second direction, which can increase the light emitting angle of at least some of the light emitted from the first color light emitting element 221 in the first direction, such that the attenuation parameter of the first color light emitting element 221 in the first direction is larger.

Optionally, as shown in FIG. 14 and FIG. 15, FIG. 14 is a schematic diagram of the structure of another display panel according to some embodiments of the present application, and FIG. 15 is a schematic diagram of a cross-sectional structure of the display panel at E1-E2 illustrated in FIG. 14. The first bump structure 231 includes at least one sub-bump 2311, and the at least one sub-bump 2311 of the first bump structure 231 is a block bump 23112, and a spacing is disposed between the edge of the orthographic projection of the block bump 23112 on the substrate 21 and the edge of the orthographic projection of the corresponding light emitting element 22 on the substrate 21. The ratio of the length and width of the block bump 23112 is less than 2. In this way, the light emitting angle of the light emitted by the light emitting element 22 can be adjusted in a plurality of directions by the block bump 23112. The light beam emitted from the light emitting element 22 at a smaller light emitting angle can be adjusted to the light beam at a larger light emitting angle, and the uniformity of the light emitted from the light emitting element 22 is improved at each light emitting angle, and the display effect of the display panel is improved.

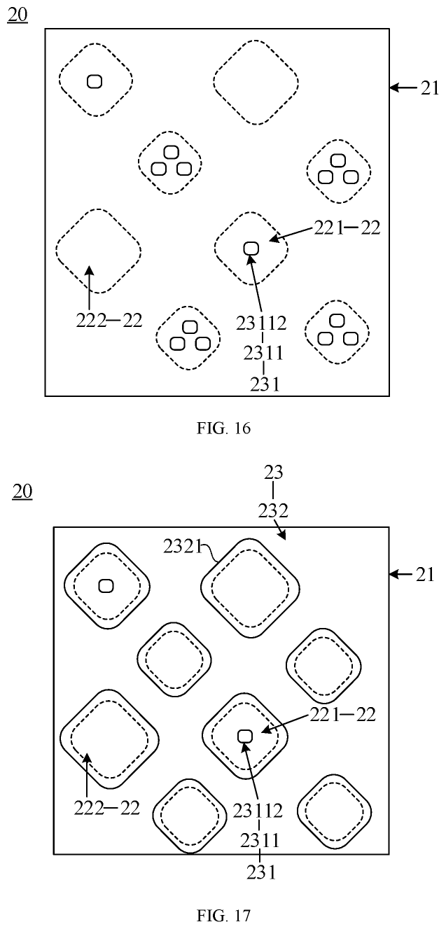

FIG. 16 and FIG. 17 are schematic diagrams of the structure of another display panel according to some embodiments of the present application, in which the quantity of block bumps 23112 of the first bump structure 231 corresponding to the plurality of types of light emitting elements 22 can be different, and the block bumps 23112 of the display panel 20 can be flexibly arranged according to the color shift of different display panels 20, such that the light attenuation parameters of the light beam of the plurality of types of light emitting elements 22 remain as consistent as possible for different use environments of display panel 20, which can improve the applicability of the display panel 20.

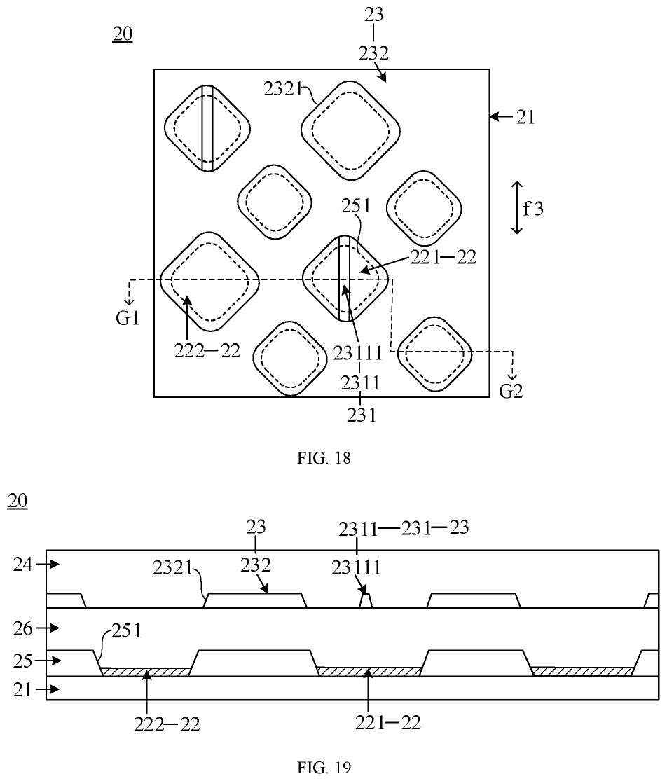

Optionally, as shown in FIG. 18 and FIG. 19, FIG. 18 is a schematic diagram of the structure of another display panel according to some embodiments of the present application, and FIG. 19 is a schematic diagram of a cross-sectional structure of the display panel at G1-G2 illustrated in FIG. 18. The display panel 20 further includes a pixel definition layer 25, the pixel definition layer 25 is disposed on the side of the optical adjustment pattern 23 toward the substrate 21, the pixel definition layer 25 has a plurality of pixel openings 251, and the light emitting element 22 are disposed in the pixel openings 251.

The optical adjustment pattern 23 further includes a second bump structure 232, the second bump structure 232 has a plurality of first openings 2321, an orthographic projection of the pixel opening 251 on the substrate 21 is within the orthographic projection of the first opening 2321 on the substrate 21, and an orthographic projection of the first bump structure 231 on the substrate 21 is within the orthographic projection of the first opening 2321 on the substrate 21 in the substrate 21.

Because the refractive index of the second bump structure 232 is less than the refractive index of the first planarization layer 24 covering the second bump structure 232, the second bump structure 232 is provided around the pixel opening 251, such that the light beam emitted from the light emitting element 22 in the pixel opening 251 is fully reflected on the side of the second bump structure 232 to enhance the frontal light emitting efficiency of display panel.

Moreover, the first bump structure 231 on the display panel 20 causes the light emitting angle of some of the light emitted from at least some of the light emitting elements 22 to increase, such that the attenuation parameters of the light emitted from the plurality of types of light emitting elements 22 remain as consistent as possible, and the problem of large visual character bias of the display panel is improved. In this way, by the combined arrangement of the first bump structure 231 and the second bump structure 232, the problem color shift at large-view angle of the display panel 20 is improved while improving the frontal light emitting efficiency of the display panel 20, and the display effect of the display panel 20 is improved.

As shown in FIG. 12, FIG. 13, and FIG. 17, the second bump structure 232 and the first bump structure 231 are provided in combination in various ways, that is, the second bump structure 232 is provided in combination with the strip bump 23111 or the block bump 23112, such that the display panel has a better display effect.

Optionally, the first bump structure 231 and as the second bump structure 232 are disposed in one layer and are formed by one-time patterning process, which simplifies the manufacturing process of the display panel 20.

Optionally, as shown in FIG. 13 and FIG. 17, the first bump structure 231 includes at least one sub-bump 2311. The sub-bump 2311 is a strip bump 23111, and the ends of the strip bump 23111 are connected to the second bump structure 232. That is, the strip bump 23111 is a one-piece structure with the second bump structure 232 and is formed by one-time patterning process.

Optionally, as shown in FIG. 18, the orthographic projection of the strip bump 23111 on the substrate 21 is in contact with two edges of the orthographic projection of the pixel opening 251 on the substrate 21 along a third direction f3 opposite to each other, and the third direction f3 is the length direction of the strip bump 23111. In this way, it is possible to make the strip bump 23111 adjust the attenuation parameter of a larger portion of the light emitted by the light emitting element 22 within the pixel opening 251, and the efficiency of the adjustment of the light emitted by the light emitting element 22 by the strip bump 23111 is improved.

Optionally, as shown in FIG. 18, the center of the orthographic projection of the first bump structure 231 on the substrate 21 is coincident with the center of the orthographic projection of the light emitting element 22 to the first bump structure 231 on the substrate 21. The center is the center of gravity of the orthographic projection of the first bump structure 231 on the substrate 21 or the orthographic projection of the light emitting element 22 on the substrate 21. It should be understood that when the orthographic projection of the first bump structure 231 on the substrate 21 and the orthographic projection of the light emitting element 22 on the substrate 21 are regular figures, the center is the geometric center of the orthographic projection of the first bump structure 231 on the substrate 21 or the orthographic projection of the light emitting element 22 on the substrate 21. In this way, it is possible to make the light emitted by the light emitting element 22 in the case that the light emitting angle of the first bump structure 231 is adjusted to be more symmetrical, and it is possible to display a more uniform luminance in all directions of the panel 20.

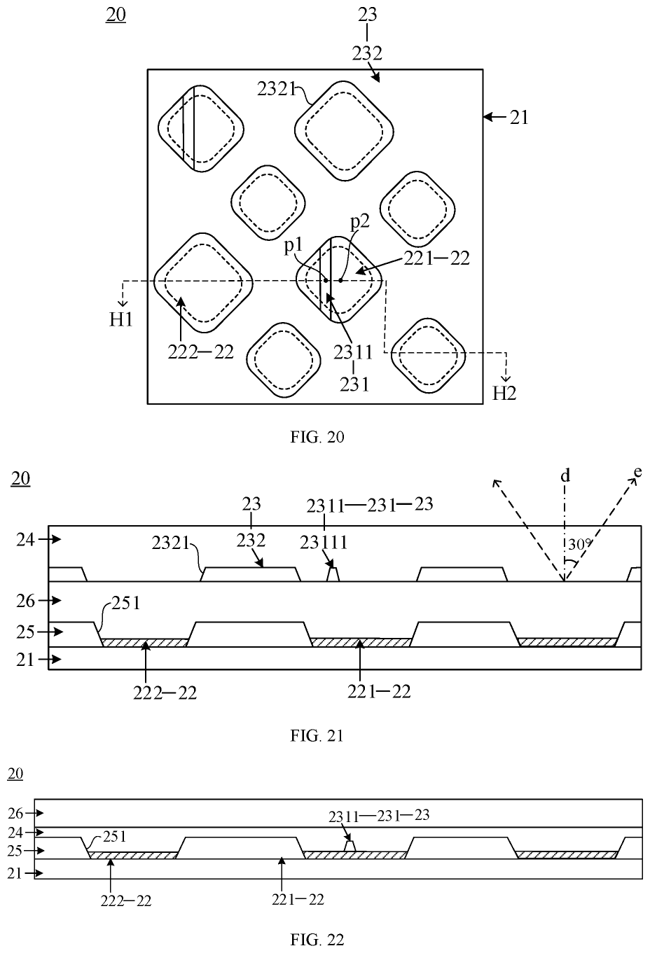

Optionally, as shown in FIG. 20 and FIG. 21, FIG. 20 is a schematic diagram of the structure of another display panel according to some embodiments of the present application, and FIG. 21 is a schematic diagram of a cross-sectional structure of the display panel at H1-H2 illustrated in FIG. 20. The center p1 of the orthographic bump of the first bump structure 231 on the substrate 21 is in the determined direction of the center p2 of the orthographic projection of the light emitting element 22 corresponding to the first bump structure 231 on the substrate 21. In some display panels, the attenuation parameters of light emitted by light emitting elements of different colors in the same direction are inconsistent at positive and negative same light emitting angles, resulting in a color shift in the final display of the display panel. In FIG. 21, the normal of the light emitting surface of the display panel 20 is d. The light emitting angle along direction e is a positive light and the light emitting angle along the opposite direction of direction e is a negative light. FIG. 21 illustrates a positive 30° light emitting angle and a negative 30° light emitting angle.

Referring again to FIG. 21, the position of the first bump structure 231 is differentially arranged according to the distance between the center of the first bump structure 231 and the center of the light emitting element 22. In the case that the center of the orthographic projection of the first bump structure 231 on the substrate 21 is within a determined direction corresponding to the center of the bump of the light emitting element 22 on the substrate 21, it is possible to make the light emitting element 22 to emit more light in the determined direction and to make the light emitting element 22 to emit less light in the direction opposite to the determined direction, such that the attenuation parameters of the light emitting element 22 at positive and negative viewing angles is consistent, and the color shift problem of the display panel 20 is improved.

Exemplarily, the first bump structure 231 in FIG. 21 can also be used in a vehicle display device. Because the viewer usually views the vehicle display device through a specific viewing angle, the light emitting angle of the display panel 20 in the specified direction can be adjusted by the first bump structure 231 to fit a variety of environments of display panel.

Optionally, the first bump structure 231 includes at least one sub-bump 2311, and the thickness of the sub-bump 2311 is greater than or equal to 4 μm.

The sub-bump 2311 is a strip bump 23111, the width of the strip bump 23111 in a direction parallel to the substrate 21 ranges from 5 μm to 10 μm, or, the sub-bump 2311 is a block bump 23112, and the size of the block bump 23112 in a direction parallel to the substrate 21 ranges from 5 μm to 10 μm.

Optionally, the plurality of light emitting elements includes a red light emitting element, a green light emitting element, and a blue light emitting element. The red light emitting element is configured to emit red light, the green light emitting element is configured to emit green light, and the blue light emitting element is configured to emit blue light. The quantity of sub-structures of the first bump structure corresponding to the red light emitting element is greater than the quantity of sub-structures of the first bump structure corresponding to the blue light emitting element. The quantity of sub-structures of the first bump structure corresponding to the green light emitting element is greater than the quantity of sub-structures of the first bump structure corresponding to the blue light emitting element.

Optionally, as shown in FIG. 21, the display panel 20 further includes: a package layer 26, and the optical adjustment pattern 23 is disposed on a side of the package layer 26 distal from the substrate 21.

Optionally, as shown in FIG. 22, FIG. 22 is a schematic diagram of the structure of another display panel according to some embodiments of the present application. The display panel 20 further includes: a package layer 26, which has a multilayer structure, and the optical adjustment pattern 23 and the first planarization layer 24 is disposed on a side of at least one structural layer of the package layer 26 close to the substrate 21. The package layer 26 has a lower refractive index than the refractive index of the first planarization layer 24.

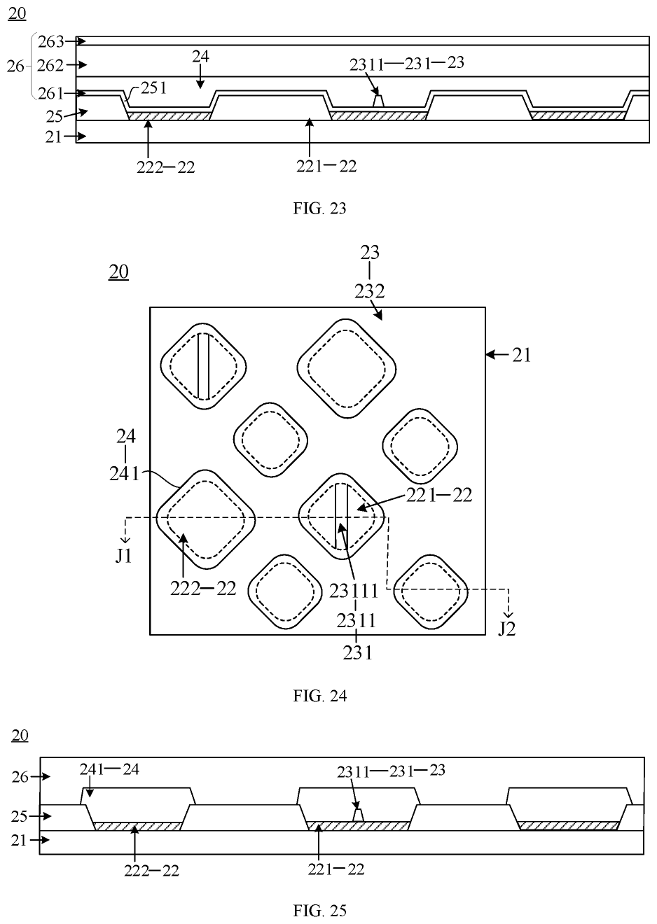

In an optional embodiment, as shown in FIG. 23, which is a schematic diagram of the structure of another display panel according to some embodiments of the present application. The display panel 20 further includes: a package layer 26, which includes a first inorganic package layer 261, an organic package layer 262, and a second inorganic package layer 263. The optical adjustment pattern 23 and the first planarization layer 24 are disposed between the first inorganic package layer 261 and the organic package layer 262. The refractive index of the first planarization layer 24 is higher than the refractive index of the organic package layer 262, and the material of the first planarization layer 25 includes a photoresist.

Optionally, in the case that the refractive index of the organic package layer 262 is high, i.e., the refractive index of the organic package layer 262 is close to the refractive index of the first planarization layer 24, the first planarization layer 24 and the organic package layer 262 are a whole structure. The organic package layer 262 with a higher refractive index is covered directly on the side of the optical adjustment pattern 23 away from the substrate during the manufacturing process of the display panel 20.

In an optional embodiment, as shown in FIGS. 24 and 25, FIG. 24 is a schematic diagram of the structure of another display panel according to some embodiments of the present application, and FIG. 25 is a schematic diagram of a cross-sectional structure of the display panel at J1-J2 illustrated in FIG. 24. The first planarization layer 24 has a third bump structure 241, and the orthographic projection of the light emitting element 22 on the substrate 21 is within the orthographic projection of the third bump structure 241 on the substrate 21. The refractive index of the third bump structure 241 is greater than the refractive index of at least one structural layer of the package layer 26, and the third bump structure 241 may be used to increase the frontal light output of the display panel 20.

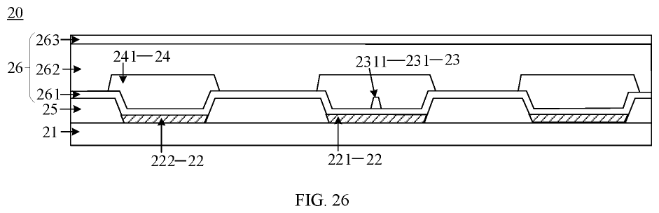

As shown in FIG. 26, which is a schematic diagram of the structure of another display panel according to some embodiments of the present application, the package layer 26 includes a first inorganic package layer 261, an organic package layer 262, and a second inorganic package layer 263. The organic package layer 262 is disposed on the side of the first planarization layer 24 and the optical adjustment pattern 23 away from the substrate 21, i.e., the optical adjustment pattern 23 and the third bump structure 241 is disposed between the first inorganic package layer 261 and the organic package layer 262. The orthographic projection of the light emitting element 22 on the substrate 21 and the orthographic projection of the optical adjustment pattern 23 on the substrate 21 are within the orthographic projection of the third bump structure 241 on the substrate 21. The refractive index of the third bump structure 241 is higher than the refractive index of the organic package layer 262, and the third bump structure 241 may be used to increase the frontal light output of the display panel 20.

In this way, by the combined provision of the first bump structure 231 and the third bump structure 241, the problem of large color shifts of the display panel 20 can be improved while improving the frontal light emitting efficiency of the display panel 20, and the display effect of the display panel 20 is improved.

In summary, embodiments of the present application provide a display panel. The display panel includes: a substrate, a plurality of light emitting elements, an optical adjustment pattern, and a first planarization layer. A first bump structure of the optical adjustment pattern is disposed in the light emitting direction of at least one light emitting element. The optical adjustment pattern increases the light emitting angle of at least part of the light emitted by the light emitting element, and improves the uniformity of the brightness of the light emitting element at different light emitting angles, and improves the display effect of the display panel.

Embodiments of the present application also provide a display device, the display device including: a power supply assembly, and a display panel, and the power supply assembly is configured to supply power to the display panel. The display panel is a display panel in any of the above embodiments.

The display device may be: a cell phone, a tablet computer, a television set, a monitor, a laptop computer, a digital photo frame, a navigator, or any other product or component having a display function.

The term “at least one of A and B” in this application is simply a description of the association relationship of the associated objects, indicating that three relationships can exist, for example, at least one of A and B, which can mean: A alone, both A and B, and B alone.

It should be noted that in the accompanying drawings, the dimensions of the layers and regions may be exaggerated for the clarity of the illustrations. It should be understood that when a component or layer is referred to as being “on” another component or layer, it may be directly over the other component, or there may be an intermediate layer. It should be understood that when an element or layer is referred to as being “under” another element or layer, it may be directly under other elements, or there may be more than one intermediate layer or element. It should also be understood that when a layer or element is referred to as being “between” two layers or elements, it may be the only layer between two layers or elements, or there may be more than one intermediate layer or element. Similar reference marks throughout indicate similar components.

In the application, the terms “first” and “second” are used for descriptive purposes only, and are not to be construed as indicating or implying relative importance. The term “plurality” refers to two or more, unless otherwise expressly limited.

The above mentioned are only optional embodiments of the present application and are not used to limit the present application. Any modification, equivalent replacement, improvement, etc. made within the spirit and principles of the present application shall be included in the scope of protection of the present application.

1. A display panel, comprising:
a substrate;
a plurality of light emitting elements, disposed on the substrate;
an optical adjustment pattern, disposed on a side, departing from the substrate, of the light emitting elements, wherein the optical adjustment pattern comprises a first bump structure corresponding to at least one light emitting element of the plurality of light emitting units, an overlapping region being present between an orthographic projection of the first bump structure on the substrate and an orthographic projection of the light emitting element corresponding to the first bump structure on the substrate, an area of the overlapping region being less than an area of the orthographic projection of the light emitting element on the substrate; and
a first planarization layer, disposed on a side, departing from the light emitting element, of the optical adjustment pattern, wherein a refractive index of the first planarization layer is greater than a refractive index of the optical adjustment pattern.

2. The display panel according to claim 1, wherein the light emitting elements comprise at least two types of light emitting elements, and the first bump structure comprises at least one sub-bump;
wherein the at least two types of light emitting elements comprise a first color light emitting element and a second color light emitting element, a sub-bump parameter of the first bump structure corresponding to the first color light emitting element is different from a sub-bump parameter of the first bump structure corresponding to the second color light emitting element, and the sub-bump parameter comprises at least one of a quantity and a size of the sub-bumps.

3. The display panel according to claim 2, wherein in at least one direction parallel to the substrate, an attenuation parameter of the first color light emitting element is less than an attenuation parameter of the second color light emitting element, the attenuation parameter being a ratio of a luminance of the light emitting element at a specified emitting angle to a maximum luminance of the light emitting element in the at least one direction parallel to the substrate;
wherein a quantity of the sub-bumps of the first bump structure corresponding to the first color light emitting element is greater than a quantity of the sub-bumps of the first bump structure corresponding to the second color light emitting element.

4. The display panel according to claim 2, wherein in at least one direction parallel to the substrate, an attenuation parameter of the first color light emitting element is less than an attenuation parameter of the second color light emitting element, the attenuation parameter being a ratio of a luminance of the light emitting element at a specified emitting angle to a maximum luminance of the light emitting element in the at least one direction parallel to the substrate;
wherein at least one sub-bump of the first bump structure is a strip bump, and a length of the strip bump corresponding to the first color light emitting element is greater than a length of the strip bump corresponding to the second color light emitting element.

5. The display panel according to claim 1, wherein the plurality of light emitting elements comprise at least one target light emitting element, an attenuation parameter of the target light emitting element in a first direction being less than an attenuation parameter in a second direction, the first direction and the second direction being parallel to the substrate, the first direction being perpendicular to the second direction, the attenuation parameter being a ratio of a luminance of the light emitting element at a specified emitting angle to a maximum luminance of the light emitting element in the at least one direction parallel to the substrate;
wherein the first bump structure comprises at least one sub-bump, the at least one sub-bump of the first bump structure is a strip bump, a length direction of the strip bump corresponding to the target light emitting element being parallel to the second direction.

6. The display panel according to claim 1, wherein the first bump structure comprises a plurality of sub-bumps, the sub-bumps being strip bumps, length directions of the plurality of strip bumps being intersected with each other.

7. The display panel according to claim 1, wherein the first bump structure comprises a plurality of sub-bumps, the sub-bumps being strip bumps, length directions of the plurality of strip bumps being parallel to each other, the plurality of strip bumps being spaced apart.

8. The display panel according to claim 1, wherein the first bump structure comprises at least one sub-bump, the at least one sub-bump of the first bump structure being a block bump, an edge of an orthographic projection of the block bump on the substrate being spaced from an edge of an orthographic projection of the light emitting element corresponding to the block bump on the substrate.

9. The display panel according to claim 1, further comprising: a pixel definition layer, wherein the pixel definition layer is disposed on a side, facing towards the substrate, of the optical adjustment pattern, the pixel definition layer comprises a plurality of pixel openings, and the light emitting elements are disposed in the pixel openings;
wherein the optical adjustment pattern further comprises a second bump structure, the second bump structure comprises a plurality of first openings, an orthographic projection of the pixel opening on the substrate is within an orthographic projection of the first opening on the substrate, and an orthographic projection of the first bump structure on the substrate is within the orthographic projection of the first opening on the substrate.

10. The display panel according to claim 9, wherein the first bump structure and the second bump structure are disposed in one layer and are formed by one-time patterning process.

11. The display panel according to claim 10, wherein the first bump structure comprises at least one sub-bump, the sub-bump being a strip bump, both ends of the strip bump being connected to the second bump structure.

12. The display panel according to claim 9, wherein the first bump structure comprises at least one sub-bump, the sub-bump being a strip bump, an orthographic projection of the strip bump on the substrate being in contact with two opposite edges of an orthographic projection of the pixel opening on the substrate along a third direction, the third direction being a length direction of the strip bump.

13. The display panel according to claim 1, wherein a center of an orthographic projection of the first bump structure on the substrate is coincident with a center of an orthographic projection of the light emitting element corresponding to the first bump structure on the substrate.

14. The display panel according to claim 1, wherein a center of an orthographic projection of the first bump structure on the substrate is in a determined direction of a center of an orthographic projection of the light emitting element corresponding to the first bump structure on the substrate.

15. The display panel according to claim 1, wherein the first bump structure comprises at least one sub-bump, the sub-bump has a top surface, a bottom surface and a side surface connecting the bottom surface and the top surface, and an angle between the side surface and the bottom surface is an acute angle.

16. The display panel according to claim 1, further comprising: an organic package layer, wherein the organic package layer is disposed on a side, departing from the substrate, of the first planarization layer and the optical adjustment pattern;
wherein the first planarization layer comprises a third bump structure, an orthographic projection of the light emitting element on the substrate and an orthographic projection of the optical adjustment pattern on the substrate being within an orthographic projection of the third bump structure on the substrate, a refractive index of the third bump structure being greater than a refractive index of the organic package layer.

17. A display device, comprising: a power supply assembly, and a display panel, wherein the display panel comprises:
a substrate;
a plurality of light emitting elements, disposed on the substrate;
an optical adjustment pattern, disposed on a side, departing from the substrate, of the light emitting elements, wherein the optical adjustment pattern comprises a first bump structure corresponding to at least one light emitting element of the plurality of light emitting units, an overlapping region being present between an orthographic projection of the first bump structure on the substrate and an orthographic projection of the light emitting element corresponding to the first bump structure on the substrate, an area of the overlapping region being less than an area of the orthographic projection of the light emitting element on the substrate;
a first planarization layer, disposed on a side, departing from the light emitting element, of the optical adjustment pattern, wherein a refractive index of the first planarization layer is greater than a refractive index of the optical adjustment pattern; and
the power supply assembly is configured to supply power to the display panel.

18. The display device according to claim 17, wherein the light emitting elements comprise at least two types of light emitting elements, and the first bump structure comprises at least one sub-bump;
wherein the at least two types of light emitting elements comprise a first color light emitting element and a second color light emitting element, a sub-bump parameter of the first bump structure corresponding to the first color light emitting element is different from a sub-bump parameter of the first bump structure corresponding to the second color light emitting element, and the sub-bump parameter comprises at least one of a quantity and a size of the sub-bumps.

19. The display device according to claim 18, wherein in at least one direction parallel to the substrate, an attenuation parameter of the first color light emitting element is less than an attenuation parameter of the second color light emitting element, the attenuation parameter being a ratio of a luminance of the light emitting element at a specified emitting angle to a maximum luminance of the light emitting element in the at least one direction parallel to the substrate;
wherein a quantity of the sub-bumps of the first bump structure corresponding to the first color light emitting element is greater than a quantity of the sub-bumps of the first bump structure corresponding to the second color light emitting element.

20. The display device according to claim 18, wherein in at least one direction parallel to the substrate, an attenuation parameter of the first color light emitting element is less than an attenuation parameter of the second color light emitting element, the attenuation parameter being a ratio of a luminance of the light emitting element at a specified emitting angle to a maximum luminance of the light emitting element in the at least one direction parallel to the substrate;
wherein at least one sub-bump of the first bump structure is a strip bump, and a length of the strip bump corresponding to the first color light emitting element is greater than a length of the strip bump corresponding to the second color light emitting element.
